(19) United States
(12) Patent Application Publication
(10) Pub. No.: US 2003/0030062 A1
(43) Pub. Date: Feb. 13, 2003

(54) Methods for fabricating a laser cavity

(75) Inventors: Paige M. Holm, Phoenix, AZ (US); Barbara Foley Barenburg, Gilbert, AZ (US); Fred Richard, Scottsdale, AZ (US); Joyce Yamamoto, Chandler, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL (US)

(21) Appl. No.: 09/924,481

(22) Filed: Aug. 9, 2001

(51) Int. Cl. H01L 27/15

(52) U.S. Cl. 257/80; 257/79; 257/84

(57) ABSTRACT

High quality epitaxial layers of monocrystalline materials can be grown overlying monocrystalline substrates such as large silicon wafers by forming a compliant substrate for growing the monocrystalline layers. An accommodating buffer layer comprises a layer of monocrystalline oxide spaced apart from a silicon wafer by an amorphous interface layer of silicon oxide. The amorphous interface layer dissipates strain and permits the growth of a high quality monocrystalline oxide accommodating buffer layer. The accommodating buffer layer is lattice matched to both the underlying silicon wafer and the overlying monocrystalline material layer. Any lattice mismatch between the accommodating buffer layer and the underlying silicon substrate is taken care of by the amorphous interface layer. In addition, formation of a compliant substrate may include utilizing surfactant enhanced epitaxy, epitaxial growth of single crystal silicon onto single crystal oxide, and epitaxial growth of Zintl phase materials. The foregoing is utilized for fabricating a laser cavity of a laser.

### FIELD OF THE INVENTION

This invention relates generally to semiconductor structures and devices and to a method for their fabrication, and more specifically to semiconductor structures and devices and to the fabrication and use of semiconductor structures, devices, and integrated circuits that include a monocrystalline material layer comprised of semiconductor material, compound semiconductor material, and/or other types of material such as metals and nonmetals, and even more specifically to the fabrication and use of semiconductor structures, devices, and integrated circuits that include a monocrystalline material layer comprised of semiconductor material, compound semiconductor material, and/or other types of material such as metals and non-metals for fabricating a laser cavity of a semiconductor laser.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material. Furthermore, if a thin film of high quality monocrystalline material could be realized beginning with a bulk wafer such as a silicon wafer, a laser cavity of a semiconductor laser could be achieved that took advantage of the best properties of both the silicon and the high quality monocrystalline material.

Accordingly, a need exists for a semiconductor structure that provides a high quality monocrystalline film or layer over another monocrystalline material and for a process for making such a structure that can be utilized in the formation of a laser cavity. In other words, there is a need for providing the formation of a monocrystalline substrate that is compliant with a high quality monocrystalline material layer so that true two-dimensional growth can be achieved for the formation of quality semiconductor structures, devices and integrated circuits having grown monocrystalline film having the same crystal orientation as an underlying substrate that can be utilized in the formation of a laser cavity of an optical laser. This monocrystalline material layer may be comprised of a semiconductor material, a compound semiconductor material, and other types of material such as metals and non-metals.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer;

FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9-12 illustrate schematically, in cross-section, the formation of a device structure in accordance with another embodiment of the invention;

FIGS. 13-16 illustrate a probable molecular bonding structure of the device structures illustrated in FIGS. 9-12;

FIGS. 17-20 illustrate schematically, in cross-section, the formation of a device structure in accordance with still another embodiment of the invention;

FIGS. 21-23 illustrate schematically, in cross-section, the formation of yet another embodiment of a device structure in accordance with the invention;

FIG. 24 illustrates schematically, in cross-section view, a portion of a semiconductor structure that includes a monocrystalline silicon substrate that is provided in the process for fabrication a laser cavity in accordance with the present invention;

FIG. 25 illustrates a top view of a portion of a semiconductor structure of FIG. 24 that includes a monocrystalline silicon substrate, which is provided in the process for fabrication a laser cavity in accordance with the present invention; and

FIG. 26 illustrates a semiconductor structure with a first facet and a second facet defining a laser cavity that is fabricated in accordance with the present invention;

FIGS. 27 and 28 illustrate a process for fabricating a laser cavity in accordance with an embodiment of the present invention;

FIG. 29 illustrates, in cross section, an exemplary embodiment of a edge emitting laser and a wave guide in accordance with the present invention; and

FIG. 30 illustrates in cross section the exemplary embodiment of a laser system of the present invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

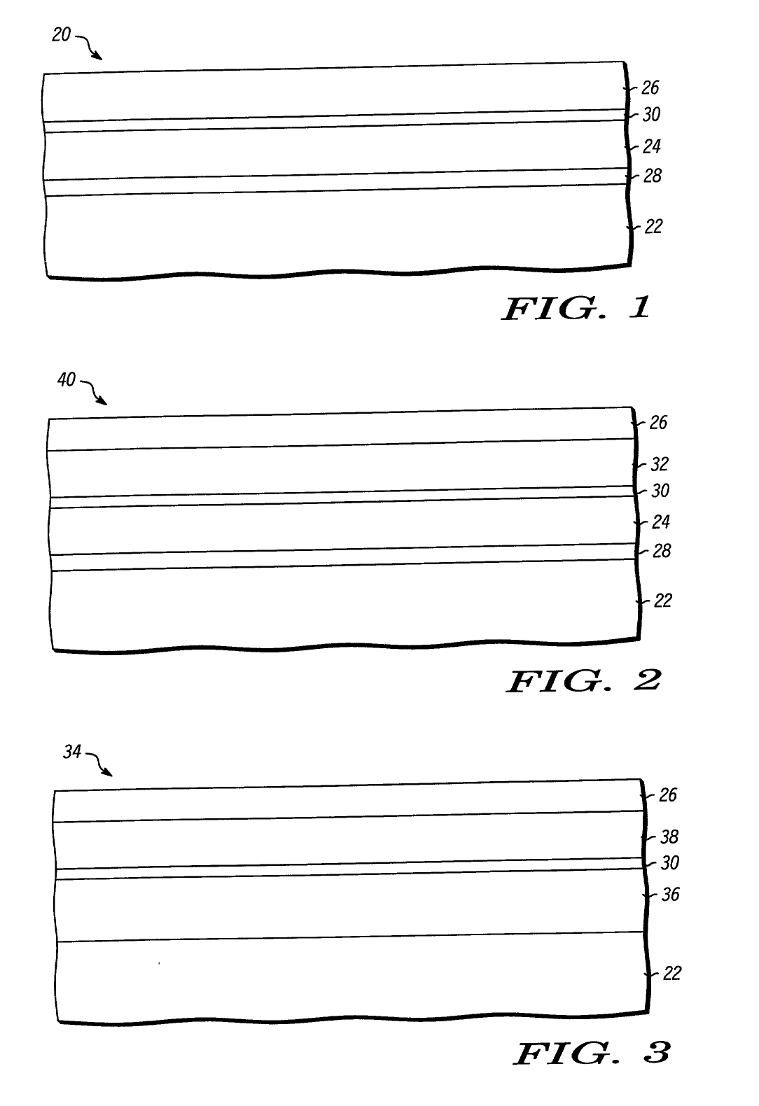

FIG. 1 illustrates schematically, in cross section, a portion of a semiconductor structure 20 in accordance with an embodiment of the invention. Semiconductor structure 20 includes a monocrystalline substrate 22, accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If the amorphous intermediate layer does not relieve such strain, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 mn.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. However, monocrystalline material layer 26 may also comprise other semiconductor materials, metals, or non-metal materials, which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides a true compliant substrate for subsequent processing—e.g., formation of the monocrystalline material layer 26.

The processes previously described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the monocrystalline material layer 26 from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a 45-degree rotation with respect to the substrate silicon lattice structure.

An accommodating buffer layer formed of these zirconate or hafnate materials is suitable for the growth of a monocrystalline material layer, which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is 1-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown on the template layer. The resulting lattice structure of the compound semiconductor material exhibits a 45-degree rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBal₁₋ₓTiO₃, where x ranges from 0 to 1, having a thickness of about 2-100 nm and preferably a thickness of about 5-15 nm. Where the monocrystalline layer comprises a compound semiconductor material, the II-VI compound semiconductor material can be, for example, zinc selenide (ZnSe) or zinc sulfur selenide (ZnSSe). A suitable template for this material system includes 1-10 monolayers of zinc-oxygen (Zn—O) followed by 1-2 monolayers of an excess of zinc followed by the selenidation of zinc on the surface. Alternatively, a template can be, for example, 1-10 monolayers of strontium-sulfur (Sr—S) followed by the ZnSeS.

### EXAMPLE 4

This embodiment of the invention is an example of structure 40 illustrated in FIG. 2. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The template for this structure can be the same of that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline material layer which in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 40 as illustrated in FIG. 2. Substrate material 22, accommodating buffer layer 24, monocrystalline material layer 26 and template layer 30 can be the same as those described above in example 2. In addition, additional buffer layer 32 is inserted between the accommodating buffer layer and the overlying monocrystalline material layer. The buffer layer, a further monocrystalline material that in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The additional buffer layer 32 preferably has a thickness of about 10-30 nm. Varying the composition of the buffer layer from GaAs to InGaAs serves to provide a lattice match between the underlying monocrystalline oxide material and the overlying layer of monocrystalline material, which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 3. Substrate material 22, template layer 30, and monocrystalline material layer 26 may be the same as those described above in connection with example 1.

Amorphous layer 36 is an amorphous oxide layer, which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z} TiO₃ (where z ranges from 0 to 1), which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

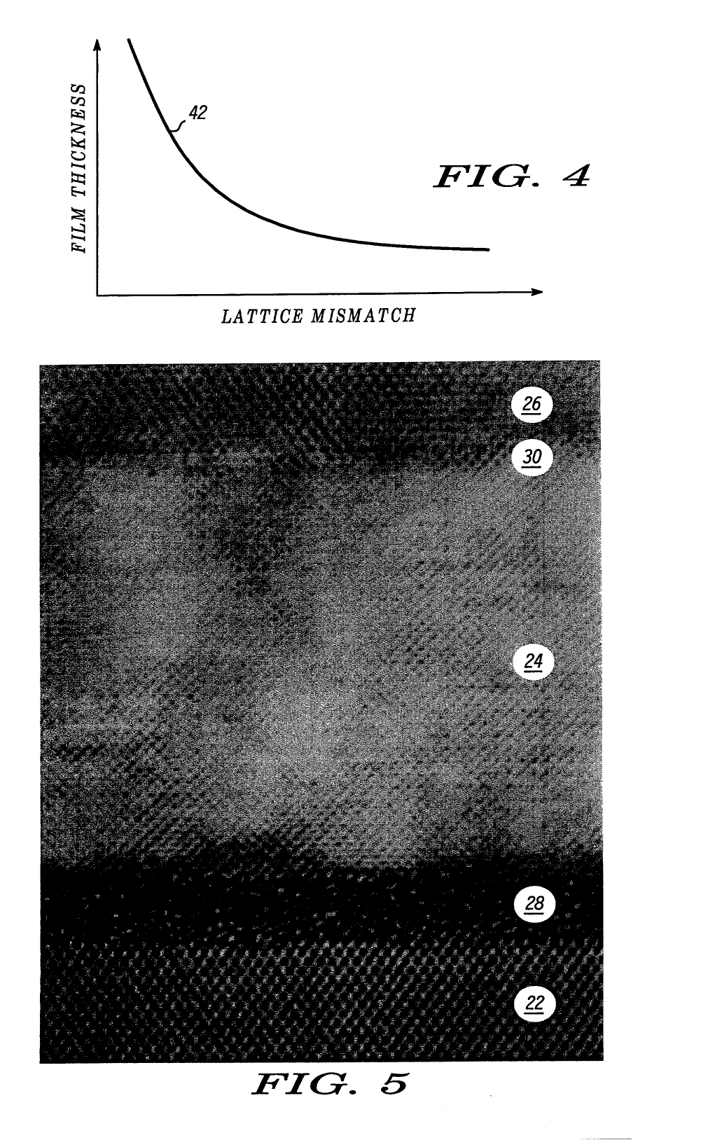

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of about 750° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of about 750° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a SrO—Ga bond, and arsenic is subsequently introduced with the gallium to form the GaAs.

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

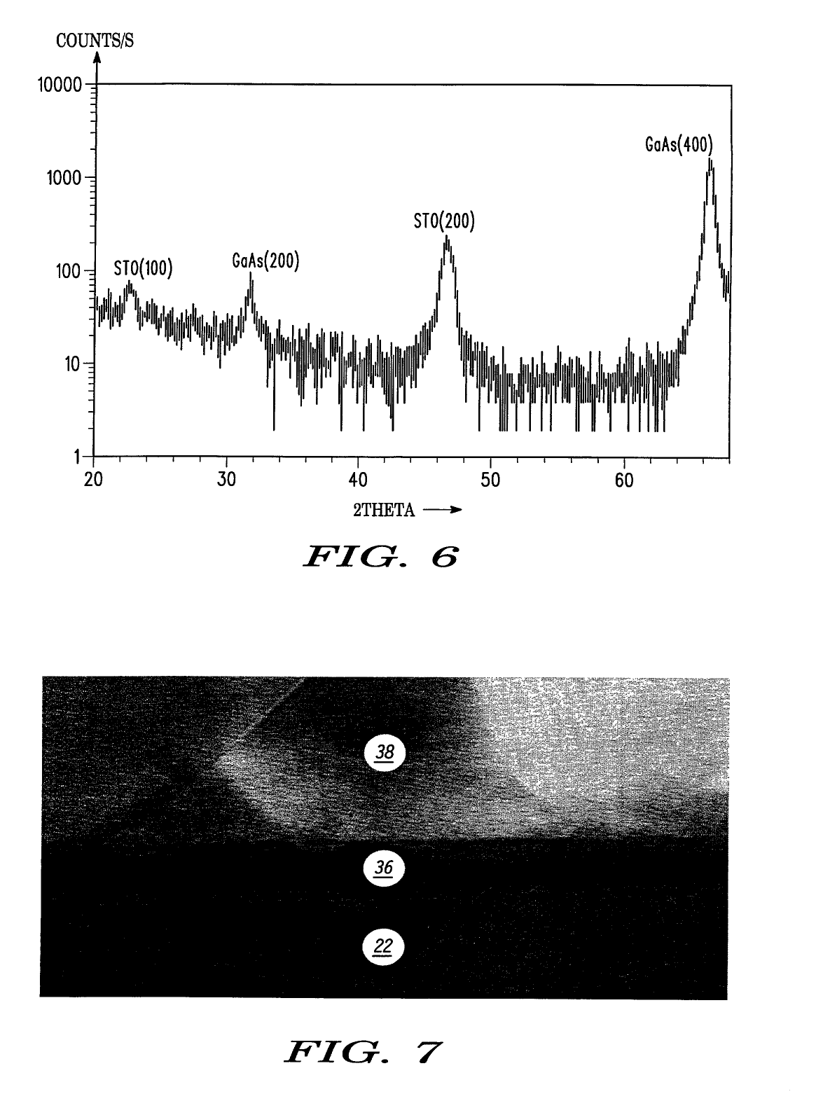

FIG. 6 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above with the addition of an additional buffer layer deposition step. The additional buffer layer 32 is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

FIG. 7 is a high resolution TEM of semiconductor material manufactured in accordance with the embodiment of the invention illustrated in FIG. 3. In accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) orientated and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

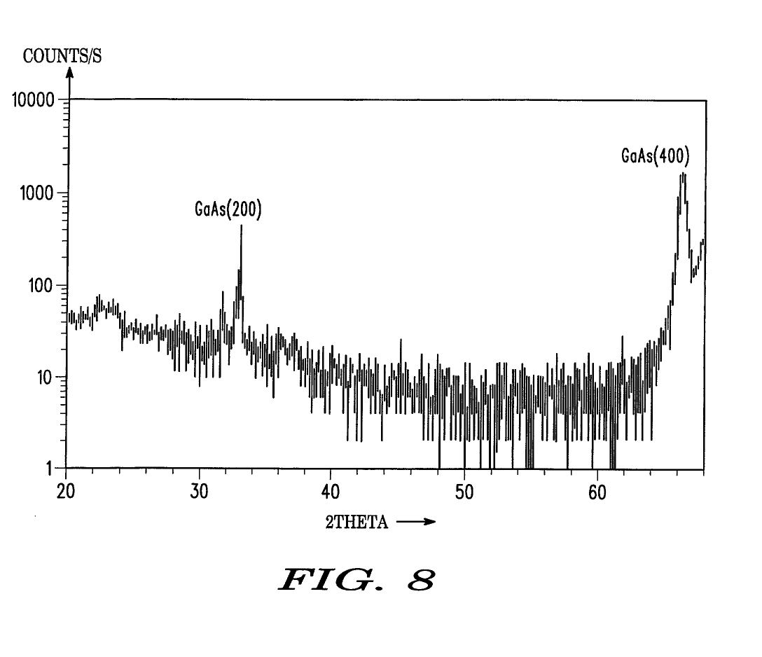

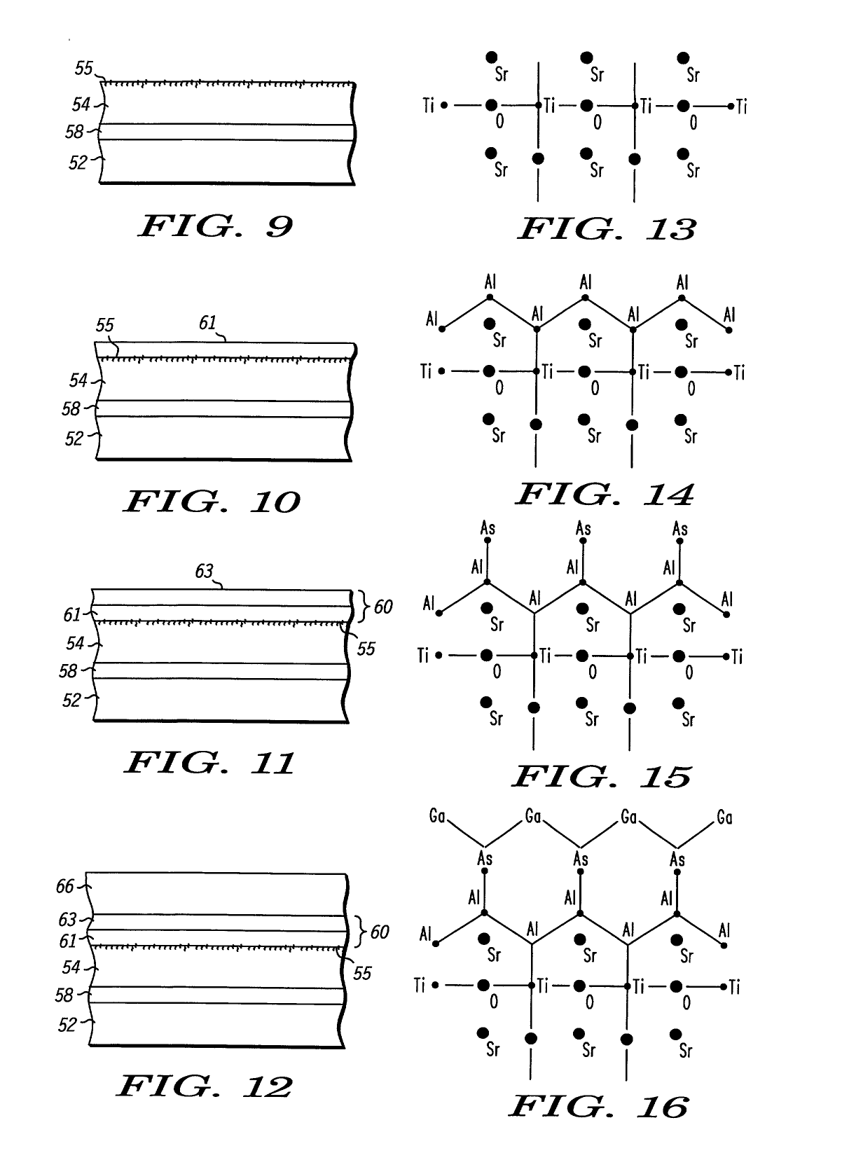

The formation of a device structure in accordance with another embodiment of the invention is illustrated schematically in cross-section in FIGS. 9-12. Like the previously described embodiments referred to in FIGS. 1-3, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 9-12 utilizes a template that includes a surfactant to facilitate layer-by-layer monocrystalline material growth.

Turning now to FIG. 9, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference layer 24 in FIGS. 1-2 and any of those compounds previously described with reference to layer 36 in FIG. 3, which is formed from layers 24 and 28 referenced in FIGS. 1 and 2.

Layer 54 is grown with a strontium (Sr) terminated surface represented in FIG. 9 by hatched line 55 which is followed by the addition of a template layer 60 which includes a surfactant layer 61 and capping layer 63 as illustrated in FIGS. 10 and 11. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one to two monolayers, over layer 54 as illustrated in FIG. 10 by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a Group V element such as arsenic, for example, to form capping layer 63 as illustrated in FIG. 11. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, CVD, MOCVD, MEE, ALE, PVD, CSD, PLD, and the like to form the final structure illustrated in FIG. 12.

FIGS. 13-16 illustrate possible molecular bond structures for a specific example of a compound semiconductor structure formed in accordance with the embodiment of the invention illustrated in FIGS. 9-12. More specifically, FIGS. 13-16 illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layers 28 and 22, respectively in FIGS. 1 and 2, illustrates a critical thickness of about 1000 Angstroms where the two-dimensional (2D) and three-dimensional (3D) growth shifts because of the surface energies involved. In order to maintain a true layer by layer growth (Frank Van der Mere growth), the following relationship must be satisfied:

δ_{STO}>(δ_{INT}+δ_{GaAs})

where the surface energy of the monocrystalline oxide layer 54 must be greater than the surface energy of the amorphous interface layer 58 added to the surface energy of the GaAs layer 66. Since it is impracticable to satisfy this equation, a surfactant containing template was used, as described above with reference to FIGS. 10-12, to increase the surface energy of the monocrystalline oxide layer 54 and also to shift the crystalline structure of the template to a diamond-like structure that is in compliance with the original GaAs layer.

FIG. 13 illustrates the molecular bond structure of a strontium terminated surface of a strontium titanate monocrystalline oxide layer. An aluminum surfactant layer is deposited on top of the strontium terminated surface and bonds with that surface as illustrated in FIG. 14, which reacts to form a capping layer comprising a monolayer of Al₂Sr having the molecular bond structure illustrated in FIG. 14 which forms a diamond-like structure with an sp³ hybrid terminated surface that is compliant with compound semiconductors such as GaAs. The structure is then exposed to As to form a layer of AlAs as shown in FIG. 15. GaAs is then deposited to complete the molecular bond structure illustrated in FIG. 16, which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 54 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising Germanium (Ge), for example, to form high efficiency photocells.

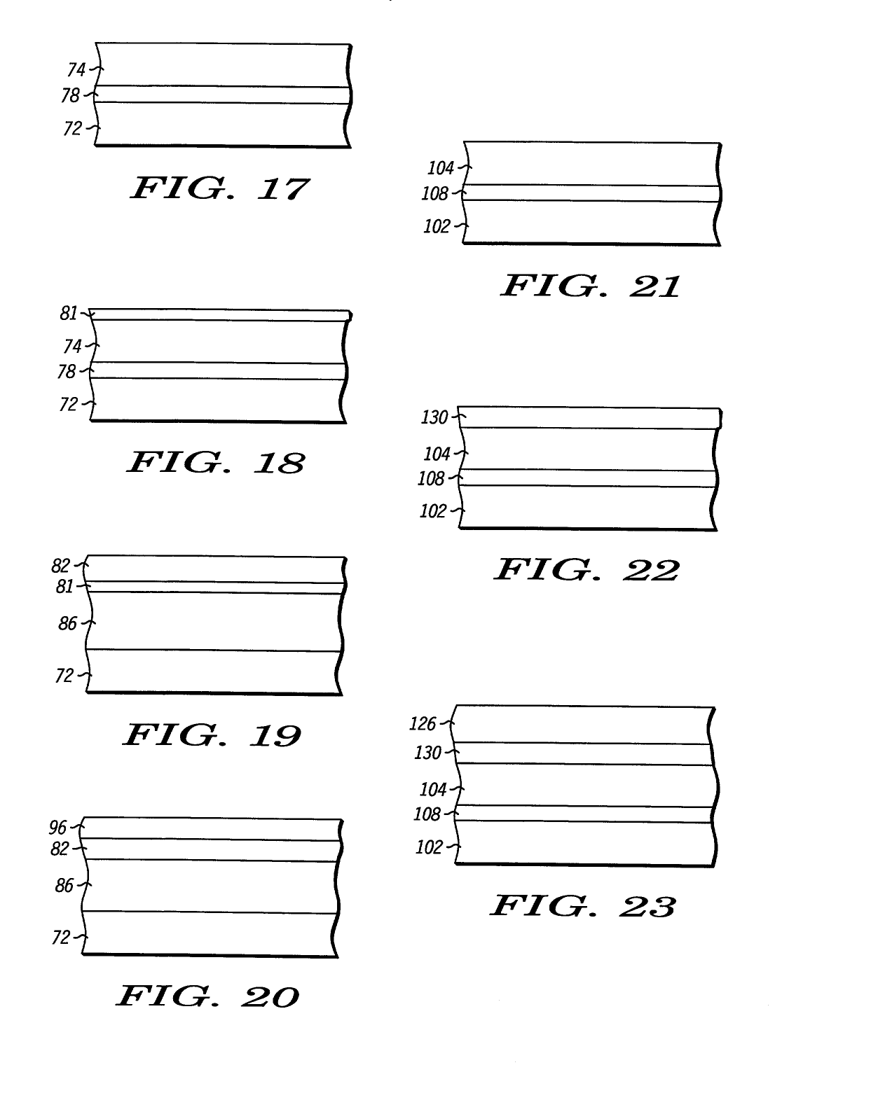

Turning now to FIGS. 17-20, the formation of a device structure in accordance with still another embodiment of the invention is illustrated in cross-section. This embodiment utilizes the formation of a compliant substrate, which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 17. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-3.

Next, a silicon layer 81 is deposited over monocrystalline oxide layer 74 via MBE, CVD, MOCVD, MEE, ALE, PVD, CSD, PLD, and the like as illustrated in FIG. 18 with a thickness of a few hundred Angstroms but preferably with a thickness of about 50 Angstroms. Monocrystalline oxide layer 74 preferably has a thickness of about 20 to 100 Angstroms.

Rapid thermal annealing is then conducted in the presence of a carbon source such as acetylene or methane, for example at a temperature within a range of about 800° C. to 1000° C. to form capping layer 82 and silicate amorphous layer 86. However, other suitable carbon sources may be used as long as the rapid thermal annealing step functions to amorphize the monocrystalline oxide layer 74 into a silicate amorphous layer 86 and carbonize the top silicon layer 81 to form capping layer 82 which in this example would be a silicon carbide (SiC) layer as illustrated in FIG. 19. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, a compound semiconductor layer 96, such as gallium nitride (GaN) is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an intermediate single crystal oxide layer that is amorphosized to form a silicate layer, which adsorbs the strain between the layers. Moreover, unlike past use of a SiC substrate, this embodiment of the invention is not limited by wafer size, which is usually less than 50 mm in diameter for prior art SiC substrates.

The monolithic integration of nitride containing semiconductor compounds containing group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

FIGS. 21-23 schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two dimensional layer by layer growth.

The structure illustrated in FIG. 21 includes a monocrystalline substrate 102, an amorphous interface layer 108 and an accommodating buffer layer 104. Amorphous interface layer 108 is formed on substrate 102 at the interface between substrate 102 and accommodating buffer layer 104 as previously described with reference to FIGS. 1 and 2. Amorphous interface layer 108 may comprise any of those materials previously described with reference to amorphous interface layer 28 in FIGS. 1 and 2. Substrate 102 is preferably silicon but may also comprise any of those materials previously described with reference to substrate 22 in FIGS. 1-3.

A template layer 130 is deposited over accommodating buffer layer 104 as illustrated in FIG. 22 and preferably comprises a thin layer of Zintl type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity, which absorbs stress build up between layers having lattice mismatch. Materials for template 130 may include, but are not limited to, materials containing Si, Ga, In, and Sb such as, for example, AlSr₂, (MgCaYb)Ga₂, (Ca,Sr,Eu,Yb)In₂, BaGe₂As, and SrSn₂As₂.

A monocrystalline material layer 126 is epitaxially grown over template layer 130 to achieve the final structure illustrated in FIG. 23. As a specific example, an SrAl₂ layer may be used as template layer 130 and an appropriate monocrystalline material layer 126 such as a compound semiconductor material GaAs is grown over the SrAl₂. The Al—Ti (from the accommodating buffer layer of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes an sp³ hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications, which include the monolithic integration of III-V and Si devices and the monolithic integration of high-k dielectric materials for CMOS technology.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers, which form semiconductor structures, devices and integrated circuits including other layers such as metal and non-metal layers. More specifically, the invention includes structures and methods for forming a compliant substrate, which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

In an embodiment of a semiconductor device of the present invention, a laser cavity of a semiconductor laser can be fabricated in accordance with the present invention. In this detailed description of the drawings, the laser cavity of the semiconductor laser is illustratively fabricated for an edge-emitting laser. The edge-emitting laser can be configured to provide any number of visible, near infrared and infrared emissions of light.

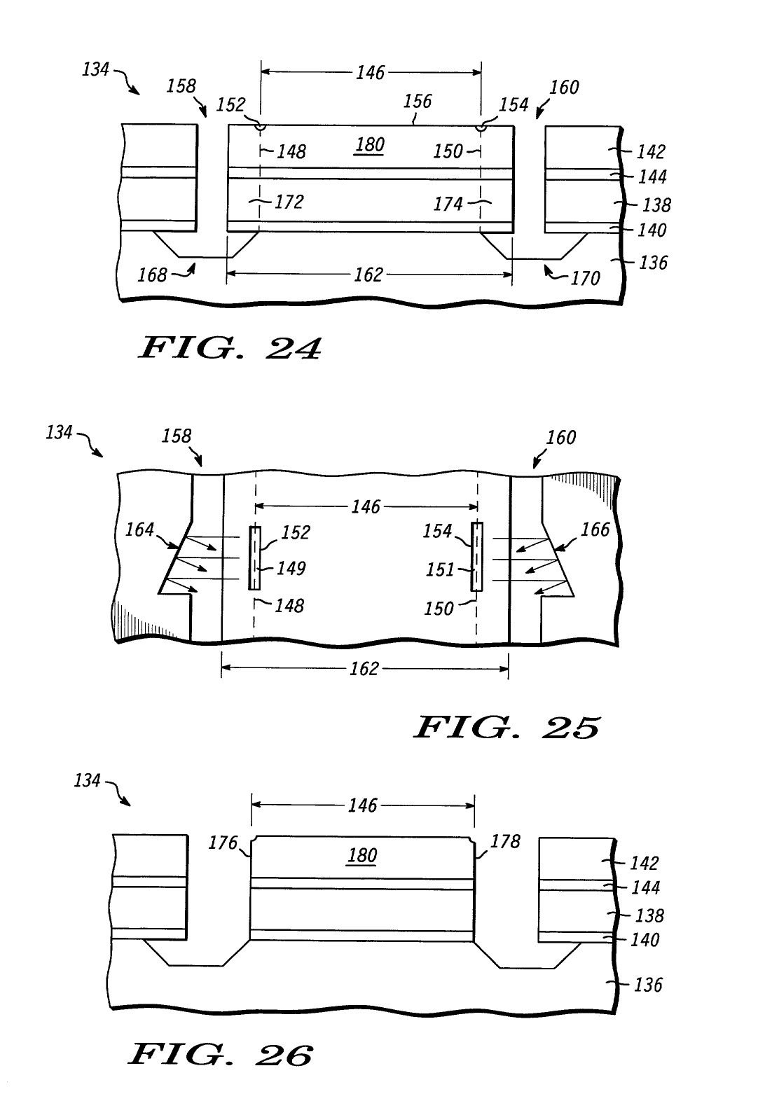

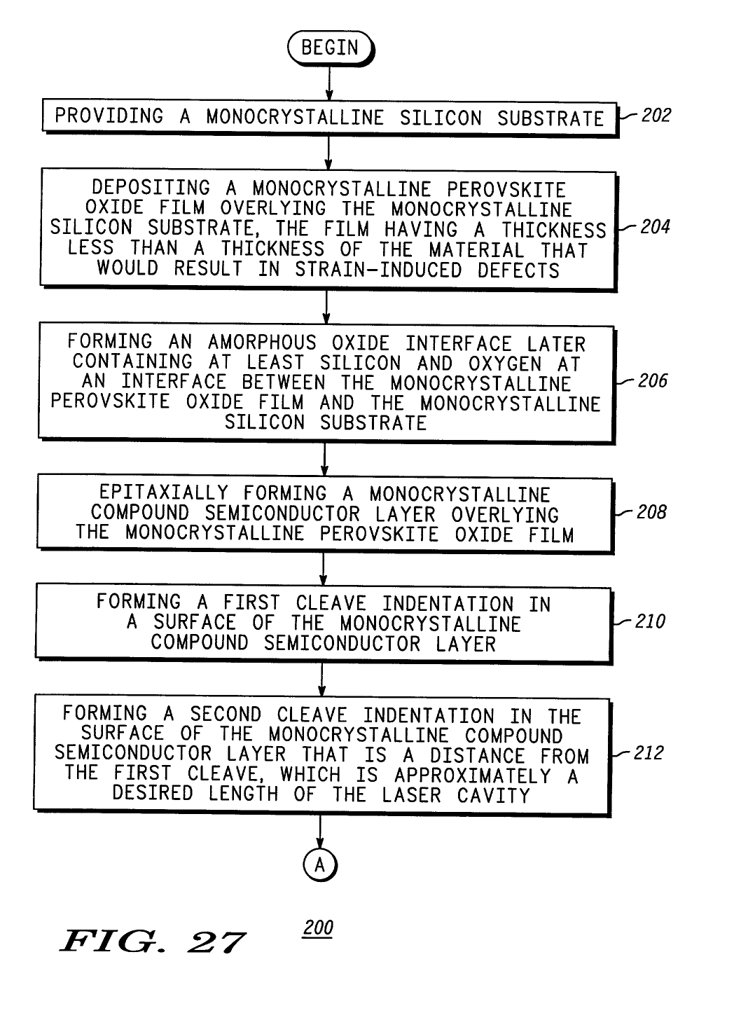

Referring to FIGS. 24 and 27-28, a cross-section view is illustrated of a portion of a semiconductor structure 134 and a process 200 is illustrated for fabricating a laser cavity, respectively, in accordance with an embodiment of the present invention. The portion of the semiconductor structure 134 includes a monocrystalline silicon substrate 136 that is provided in the process for fabrication of a laser cavity (step 202 of FIG. 27). The process for fabricating the laser cavity is also comprised of depositing a monocrystalline perovskite oxide layer 138 to overly the monocrystalline silicon substrate 136, and the thickness of the monocrystalline perovskite oxide layer 138 deposited to overly the monocrystalline silicon substrate 136 is about less than a thickness of the monocrystalline perovskite oxide layer 138 that would result in strain-induced defects (step 204 of FIG. 27). The process for fabricating the laser cavity is further comprised of forming an amorphous oxide interface layer 140 containing at least silicon and oxygen at an interface between the monocrystalline perovskite oxide 138 and the monocrystalline silicon substrate 136 (step 206 of FIG. 27) and epitaxially forming a Noncrystalline compound semiconductor layer 142 to overly the monocrystalline perovskite oxide layer 138 (step 208 of FIG. 27).

The monocrystalline compound semiconductor layer 142, monocrystalline perovskite oxide layer 138, amorphous oxide interface layer 140 and monocrystalline silicon substrate 136 correspond to the monocrystalline material layer 26, accommodating buffer layer 24, amorphous intermediate layer 28 and monocrystalline substrate 22, respectively, previously described with reference to FIGS. 1-3 and other corresponding descriptions and figures of this detailed description of the drawings. In addition, the preceding processes for forming the monocrystalline compound semiconductor layer 142, monocrystalline perovskite oxide layer 136, amorphous oxide interface layer 138 and monocrystalline silicon substrate 134 are performed as previously described in this detailed description of the drawings with reference to FIGS. 1-3 and other corresponding descriptions and figures of this detailed description of the drawings for the monocrystalline material layer 26, accommodating buffer layer 24, amorphous intermediate layer 28 and monocrystalline substrate 22. Furthermore, the process for fabricating the laser cavity can be comprised of other processes previously described in this detailed description of the drawings for forming these or additional layers. For example, a template layer 144 corresponding to the template layer 30 of FIGS. 1-3 can be formed as illustrated in FIG. 24, and an additional buffer layer 32, an amorphous layer 36 and/or an additional monocrystalline layer 38 can be formed as previously described with reference to FIG. 1-3 and other corresponding descriptions and figures of the detailed description of the drawings.

Once the monocrystalline material layer 142 is epitaxially formed to overly the monocrystalline perovskite oxide layer 138 (step 208 of FIG. 27), the laser cavity is formed from the monocrystalline material layer 142. As the process for fabricating the laser cavity of the present invention forms the laser cavity from the monocrystalline material layer 142, different bandgap semiconductors can be used for the monocrystalline material layer 142 to produce one of a variety of wavelengths of light emitted by a laser. The wavelengths of the light emitted from the laser can be obtained with the selection of binary, ternary and quaternary composition for the monocrystalline material layer 142. For example, the monocrystalline material layer 142 can be InGaP, InAIP, InGaAIP, GaN, InGaN and InGaAIN for visible light emission, GaAs, AlGaAs, InGaAs, InGaAlAs and InGaAsP for near infrared light emission and InP, InGaAs, InAlAs, InGaAlAs, InGaAsP and InGaAsN for infrared light emission. The wavelength of the light emitted from the laser is determined in a well-known manner by selecting a desired cavity length that corresponds to a wavelength that falls within a gain curve for the compound material (i.e., the longitudinal modes are supported by the desired cavity length for a given index of refraction).

The process for fabricating the laser cavity of the present invention includes forming a first cleave indentation 152 in the surface 156 of the monocrystalline compound semiconductor layer 142 (step 210 of FIG. 27). In addition, the process for fabricating the laser cavity of the present invention includes forming a second cleave indentation 154 in the surface 156 of the monocrystalline compound semiconductor layer 142 that is a distance 146 from the first cleave indentation 152, which is approximately a desired length of the laser cavity (step 212 of FIG. 27). The distance 146 is the distance between the nadirs of the cleave indentations. As used in this detailed description of the drawings, the “desired length of the laser cavity” shall mean the length of the cavity of the laser that provides a laser configured to produce emissions of light with a desired wavelength that falls within the gain curve of the compound material” and “approximately” in this particular context shall mean “within tolerances that provide the laser having the desired length of the laser cavity.” The first cleave indentation 152 and the second cleave indentation 154 are preferably formed along crystal planes 148, 150 of the monocrystalline compound semiconductor layer 142 and configured to provide a first scribe line 149 at the nadir of the cleave indentation 152 and a second scribe line 151 at the nadir of the cleave indentation 154 that are used for a cleaving operation.

More specifically and with continuing reference to FIGS. 24 and 27-28, the first cleave indentation 152 and second cleave indentation 154 are preferably formed with the selective removal of material from the surface 156 of the monocrystalline compound semiconductor layer 142 along the scribe lines 149, 151 of the monocrystalline compound semiconductor layer 142. The selective removal of material from the surface 156 of the monocrystalline compound semiconductor layer 142 can be accomplished with any number of techniques, processes or devices. For example, the surface 156 of the monocrystalline compound semiconductor layer 142 can be coated (e.g., photolithographically patterned) with a resist and wet etched (i.e., immersion in etch baths) or dry etched (i.e., plasma driven) or laser scribed to selectively remove material from the surface 156 of the monocrystalline compound semiconductor layer 142.

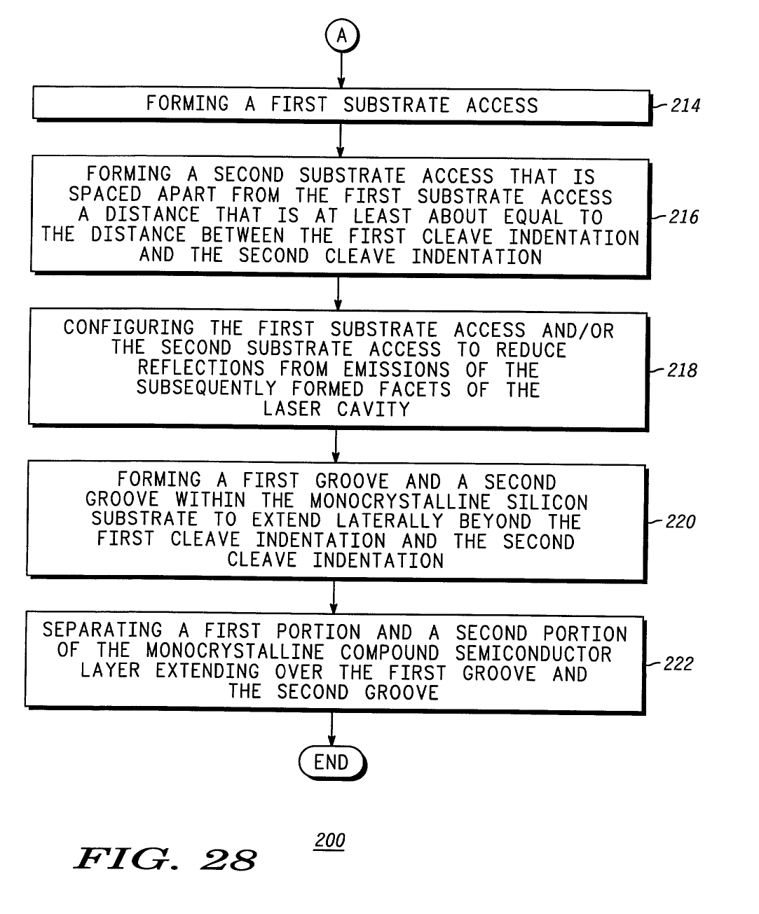

The material of the monocrystalline semiconductor layer 142 is also selectively removed with any of number of processes, techniques and devices to form a first substrate access 158 and a second substrate access 160 that is spaced apart from the first substrate access 158 a distance 162 that is at least about equal to and preferably greater than the distance 146 between the first cleave indentation 152 and the second cleave indentation 154 (steps 214 and 216 of FIG. 28). Therefore, the distance 162 between the first substrate access 158 and the second substrate access 160 is sufficient in magnitude with respect to the distance 146 between the first cleave indentation 152 and the second cleave indentation 154 to assure that the formation of the substrate accesses do not unduly reduce production yields of facets under normal production variations. In addition, material of the template layer 144, monocrystalline perovskite oxide layer 138 and amorphous oxide interface layer 140 is also selectively removed with any number of processes (step 214 and 216 of FIG. 28), techniques and devices to form the first substrate access 158 and the second substrate access 160, which can be formed with any number of configurations.

Referring to FIG. 25, which illustrates a top view of the portion of the semiconductor structure of FIG. 24, and according to an embodiment of the present invention, the first substrate access 158 and/or the second substrate access 160 opening are optionally configured to reduce reflections from emissions of the subsequently formed facets of the laser cavity (step 218 of FIG. 28). More specifically, a first outer wall 164 of the first substrate access 158 and/or a second outer wall 166 of the second substrate access 160 are configured for a non-parallel orientation with respect to the first cleave indentation 152 and the second cleave indentation 154, such that the facets of the laser cavity formed by cleave operations performed at the first cleave indentation 152 and the second cleave indentation 154 are configured for a non-parallel orientation with respect to the first outer wall 164 and the second outer wall 166. As can be appreciated by one of ordinary skill in the art, the non-parallel orientation of the first outer wall 164 and/or the second outer wall 166 with respect to the facets of the laser cavity can provide a reflection of the light emitted from the facets of the laser cavity that reduce undesired reflections. However, according to another embodiment of the present invention, the first outer wall 164 and/or the second outer wall 166 are configured for a substantially parallel orientation with respect to the facets of the laser cavity and other techniques can be utilized to reduce undesired reflections, if desired, such as applying an anti-reflective coating to the facets of the laser. Alternatively, according to yet another embodiment of the present invention, the first outer wall 164 and/or the second outer wall 166 are configured for a non-parallel orientation with respect to the facets of the laser cavity and other techniques are also utilized to reduce undesired reflections, such as applying an anti-reflective coating to the facts of the laser.

Referring again to FIGS. 24 and 27-28, once the first substrate access 158 is formed (step 214 of FIG. 28) and the second substrate access 160 are formed (step 216 of FIG. 28) in the monocrystalline compound semiconductor layer 142, template layer 144, monocrystalline perovskite oxide 138 and amorphous oxide interface layer 140, material is selectively removed from the monocrystalline silicon substrate 136 to form a first groove 168 and a second groove 170 in the monocrystalline silicon substrate 136 (step 220 of FIG. 28). The first groove 168 and second groove 170 can have any number of shapes and configurations such as a V-groove or U-groove shape. The first groove 168 and the second groove 170 are formed to extend laterally under the monocrystalline compound semiconductor layer 142 to at least the first cleave indentation 152 and the second cleave indentation 154 and can extend laterally beyond the first cleave indentation 152 and the second cleave indentation 154. The phrasing “extend laterally under the monocrystalline compound semicondustor layer to at least a cleave indentation” herein means “extending laterally under the monocrystalline compound semicondustor layer to a location on the crystal plane that passes through the cleave indentation.” The lateral removal of material in addition to the vertical removal of material from the monocrystalline compound semiconductor layer 136 can be accomplished with any number of techniques, processes and devices. For example, an isotropic wet etch can be conducted to laterally and vertically remove material from the monocrystalline compound semiconductor layer 136 such that the first groove 168 and the second groove 170 extends laterally under the monocrystalline compound semiconductor layer 142 to at least the first cleave indentation 152 and the second cleave indentation 154.

Once the first groove 168 and the second groove 170 are formed in the monocrystalline silicon substrate 136 (step 220 of FIG. 28), a cleaving operation is conducted to separate a first portion 172 of the semiconductor structure 134 along the first scribe line 149 that is extending over the first groove 168 and a second portion 174 of the semiconductor structure 134 along the second scribe line 151 that is extending over the second groove 170 (step 222 of FIG. 28). The cleaving operation can be conducted with any number of techniques, processes or devices. For example, the cleaving operation can be conducted with an ultra-sonic cleaving technique. The cleaving operation and subsequent removal of the first portion 172 and the second portion 174 provides a semiconductor structure 134 with a first facet 176 and a second facet 178 that are approximately separated by the desired length of the laser cavity as shown in FIG. 26.

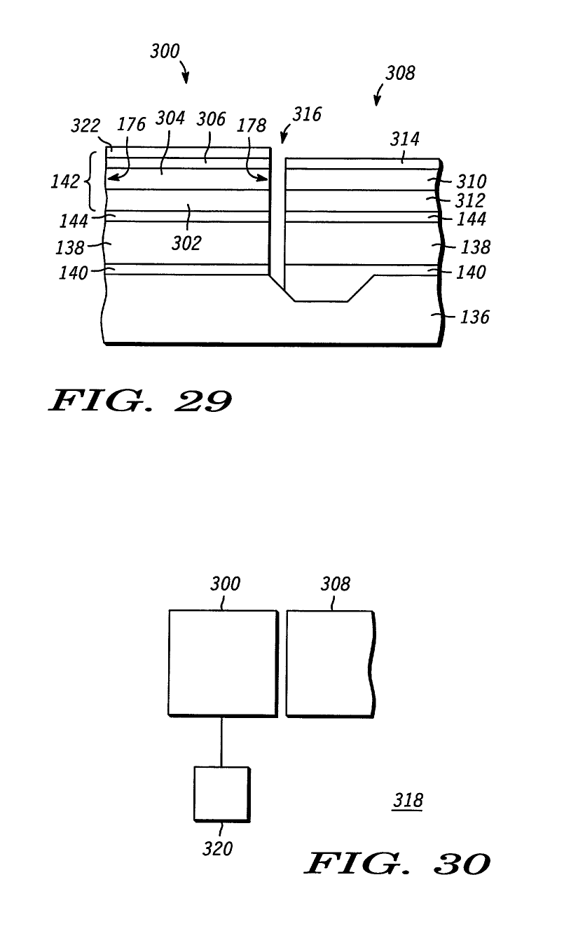

Referring to FIG. 29, the laser 300 with the first facet 176 and the second facet 178 that are separated by the desired length of the laser cavity is formed from the monocrystalline compound semiconductor layer 142 as previously described in this detailed description of the drawings. The laser 300 is formed at least partially from the monocrystalline compound semiconductor layer 142 using a selected band gap semiconductors that produces a predetermined wavelength of radiation (e.g., light) emitted from the laser 300. The predetermined wavelength of the radiation emitted from the laser 300 can be obtained by the selection of a binary, ternary or quaternary composition for the monocrystalline compound semiconductor layer 142 in addition to the selection of the cavity length. For example, the monocrystalline compound semiconductor layer can be InGaP, InAIP, InGaAIP, GaN, InGaN or InGaAIN for visible light emission, GaAs, AlGaAs, InGaAs, InGaAlAs or InGaAsP for near infrared light emission and InP, InGaAs, InAlAs, InGaAlAs, InGaAsP or InGaAsN for infrared light emission.

In accordance with an exemplary embodiment of the present invention, the monocrystalline compound semiconductor layer 142 forming the laser is comprised of a first cladding layer 302, an active layer 304 and a second cladding layer 306. The first cladding layer 302, active layer 304 and second cladding 306 can be formed of any suitable semiconductor material such as the compound semiconductor materials previously discussed in connection with the selection of the material for the monocrystalline semiconductor layer 142. For example, the first cladding layer 302 can include n-type doped AlGaAs, the active layer 304 can include GaAs, and the second cladding layer 306 can include p-type doped AlGaAs, where each of the first cladding layer 302, active layer 304 and second cladding layer 306 are epitaxially formed over the monocrystalline silicon substrate 136 to form the monocrystalline compound semiconductor layer 142 and the laser cavity is formed from this monocrystalline compound semiconductor layer 142 as previously provided in this detailed description of the drawings. Although not illustrated in FIG. 29, the laser 300 can also include insulating layers to facilitate electrical isolation and/or conducting layers to facilitate coupling of the laser to other devices and components as will be subsequently described in this detailed description of the drawings.

A wave guide 308 is generally configured to transmit and guide radiation (e.g., light) produced by the laser 300, which can be coupled to any number of devices such as a fiber optic cable (not shown). More specifically, the wave guide 308 guides radiation through a first portion or core 310, which is surrounded by a second portion or first waveguide cladding layer 312 and a third portion or second waveguide cladding layer 314. Preferably, the waveguide 308 is designed such that substantially all radiation (e.g., light) received by a first end 316 of the waveguide 308 is confined within the core 310 during transmission to a second end (not shown) of the waveguide 308. In other words, the radiation produced by the lasers 300 is preferably transmitted through the waveguide 146 with at least partial internal reflection, preferably with substantial internal reflection and more preferably with about total internal reflection.

To obtain at least partial internal reflection, substantial internal reflection or about total internal reflection, the core 310 is formed of a material having a different index of refraction than material used to form the first waveguide cladding layer 312 and/or the second waveguide cladding layer 314. More particularly, the index of refraction of the core 310 is greater than the index of refraction of the first waveguide cladding layer 312 and/or the second waveguide cladding layer 314, which can suitably be formed of the same material. In accordance with an exemplary embodiment, material selected for the core 310 has an first index of a refraction (n1), material selected for the first waveguide cladding layer 312 and the second waveguide cladding layer 314 has a second index of refraction (n2) that is about less than the first index of refraction (n1). For example, the first index of refraction (n1) and the second index of refraction (n2) can be selected for a single mode optical fiber waveguide with the dimensions and indices selected to satisfy the following:

2<(2πa)/λ)(n₁²−n₂²)^{1/2}<2.4

Suitable materials for the core 310, first wave guide cladding layer 312 and second waveguide cladding layer 314 include, but are not limited to, oxides such as alkali earth metal titanates, alkali earth metal zirconates, alkali earth metal hafnates, alkali earth metal tantalates, alkali earth metal ruthenates, alkali earth metal niobates, perovskite oxides, other suitable oxides, nitrides, plastics, glasses and the like. In accordance with one particular example, the core 310 can include strontium titanate doped with a material (e.g., an impurity), and first waveguide cladding layer 312 and second waveguide cladding layer 314 can include undoped strontium titanate such that the refractive index of the first waveguide cladding layer 312 and the second waveguide cladding layer 314 is lower than the refractive index of the core 310. In accordance with a second particular example, the core 310 can include PZT, and first waveguide cladding layer 312 and second wave guide cladding layer 314 can include PLZT such that the refractive index of the first waveguide cladding layer 312 and the second waveguide cladding layer 314 is lower than the refractive index of the core 310.

The wave guide 308 is preferably connected or formed onto the monocrystalline silicon substrate 136 using any number of connection techniques as previously described in this detailed description of the drawings. The wave guide 308 may have any number of shapes and contours and can be branched in accordance with the present invention. A branched wave guide may couple to multiple lasers or detectors. If the core 310 of the wave guide 308 is electro-optic, it may incorporate other devices such as electro-optical switches or phase modulators in any number of configurations such as a Mach Zehnder configuration or directional couplers to direct a beam from one branch to another in a tunable fashion. Therefore electrodes can be connected to the wave guide 308 to control the electro-optic effect. In like manner, ferro electric and thermal electric effects can be utilized by appropriate material choice and wave guide and electrode design, and utilized in any number of laser systems.

For example and with reference to FIG. 30, a top plan view is illustrated of an exemplary embodiment of a laser system 318 in accordance with the present invention. The laser system 318 is comprised of the edge emitting laser 300, a wave guide 308 operably coupled to the edge emitting laser 300 and a laser control circuit 320 operatively coupled to the edge emitting laser 300 to control the operation of the edge emitting laser 300. Referring to FIG. 29, an electrode layer 322 is preferably deposited over the second cladding layer 306 of the edge emitting laser 320 and patterned to form an electrode(s) as known in the art. The laser control circuit 320 may be formed at least partially in the monocrystalline semiconductor substrate 136 and coupled to the edge emitting laser 300 with one or more electrical interconnects to control operation of the edge emitting laser 300.

As can be appreciated by one of ordinary skill in the art, any number of laser systems with any number of laser configurations can be formed in accordance with the present invention, such a distributed feedback (DFB) laser. The laser systems of the present invention can be used in telecommunications, data communications, data storage and optical networks and provide an improvement over existing tunable lasers in that they provide for tuning over a wider range of wavelengths. In addition, the lasers and laser systems of the present invention are advantageous because they may be monolithically formed over a substrate such as a silicon wafer and consequently may be monolithically integrated with circuits formed on or within such a substrate.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A process for fabricating a laser cavity, comprising:
providing a monocrystalline silicon substrate;
depositing a monocrystalline perovskite oxide film overlying the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the monocrystalline silicon substrate;
epitaxially forming a monocrystalline compound semiconductor layer overlying the monocrystalline perovskite oxide film;
forming a first cleave indentation in a surface of said monocrystalline compound semiconductor layer;
forming a second cleave indentation in the surface of the monocrystalline compound semiconductor layer, said second cleave indentation separated from said first cleave indentation by a first distance that is approximately a desired length of the laser cavity;
forming a first groove and a second groove within said monocrystalline silicon substrate, said first groove formed to extend laterally under said first cleave indentation and said second groove formed to extend laterally under said second cleave indentation; and
separating a first portion and a second portion of said monocrystalline compound semiconductor layer, said first portion of said monocrystalline compound semiconductor layer extending over said first groove and said second portion of said monocrystalline compound semiconductor layer extending over said second groove, wherein said separating said first portion and said second portion of said monocrystalline semiconductor layer provides a first facet and a second facet that are approximately separated by the desired length of the laser cavity.

2. The process for fabricating the laser cavity of claim 1, further comprising:
forming a first substrate access; and
forming a second substrate access a second distance from said first substrate access that is at least equal to said first distance.

3. The process for fabricating the laser cavity of claim 1, wherein said second distance is greater than said first distance.

4. The process for fabricating the laser cavity of claim 1, wherein said first substrate access is utilized to obtain access to said monocrystalline silicon substrate for selective removal of material from said monocrystalline silicon substrate in forming said first groove.

5. The process for fabricating the laser cavity of claim 1, wherein said second substrate access is utilized to obtain access to said monocrystalline silicon substrate for selective removal of material from said monocrystalline silicon substrate in forming said second groove.

6. The process for fabricating the laser cavity of claim 1, further comprising configuring a first outer wall of said first substrate access for a non-parallel orientation with respect to said first cleave indentation such that said first facet has a non-parallel orientation with respect to said first outer wall of said first substrate access.

7. The process for fabricating the laser cavity of claim 1, further comprising configuring a second outer wall of said second substrate access for a non-parallel orientation with respect to said second cleave indentation such that said second facet has a non-parallel orientation with respect to said second outer wall of said second substrate access.

8. The process for fabricating the laser cavity of claim 1, further comprising:
configuring a first outer wall of said first substrate access for a non-parallel orientation with respect to said second cleave indentation; and
configuring a second outer wall of said second substrate access for a non-parallel orientation with respect to said second cleave indentation.

9. The process for fabricating the laser cavity of claim 1, further comprising applying an anti-reflective coating to at least one of said first facet and said second facet.

10. The process for fabricating the laser cavity of claim 1, wherein forming said first cleave indentation in said surface of said monocrystalline compound semiconductor layer is comprised of:
patterning said surface of said monocrystalline compound semiconductor layer with a resist to provide a patterned surface of said monocrystalline compound semiconductor layer; and
etching said patterned surface of said monocrystalline compound semiconductor layer.

11. The process for fabricating the laser cavity of claim 1, wherein said selective removal of material from said monocrystalline silicon substrate in forming said first groove is an isotropic wet etch.

12. The process for fabricating the laser cavity of claim 1, wherein said selective removal of material from said monocrystalline silicon substrate in forming said second groove is an isotropic wet etch.

13. The process for fabricating the laser cavity of claim 1, wherein said first groove has about a V-groove shape.

14. The process for fabricating the laser cavity of claim 1, wherein said first groove has about a U-groove shape.

15. The process for fabricating the laser cavity of claim 1, wherein forming said second cleave indentation in said surface of said monocrystalline compound semiconductor layer is comprised of:
patterning said surface of said monocrystalline compound semiconductor layer with a resist to provide a patterned surface of said monocrystalline compound semiconductor layer; and
etching said patterned surface of said monocrystalline compound semiconductor layer.

16. The process for fabricating the laser cavity of claim 1, wherein forming said first cleave indentation in said surface of said monocrystalline compound semiconductor layer is comprised of laser scribing said surface of said monocrystalline compound semiconductor layer.

17. The process for fabricating the laser cavity of claim 15, wherein said patterning said surface of said monocrystalline compound semiconductor layer with said resist to provide said patterned surface of said monocrystalline compound semiconductor layer is a photolithographic patterning.

18. The process for fabricating the laser cavity of claim 1, wherein forming said first cleave indentation in said surface of said monocrystalline compound semiconductor layer is comprised of laser scribing said surface of said monocrystalline compound semiconductor layer.

19. The process for fabricating the laser cavity of claim 1, wherein forming said second cleave indentation in said surface of said monocrystalline compound semiconductor layer is comprised of laser scribing said surface of said monocrystalline compound semiconductor layer.

20. The process for fabricating the laser cavity of claim 1, wherein said monocrystalline compound semiconductor layer is selected for a visible light emission.

21. The process for fabricating the laser cavity of claim 1, wherein said monocrystalline compound semiconductor layer is selected from the group consisting of InGaP, In AIP, INGaAIP, GaN, InGaN and InGaAIN.

22. The process for fabricating the laser cavity of claim 1, wherein said monocrystalline compound semiconductor layer is selected for a near infrared light emission.

23. The process for fabricating the laser cavity of claim 1, wherein said monocrystalline compound semiconductor layer is selected from the group consisting of GaAs, AlGaAs, InGaAs, InGaAlAs and InGaAsP.

24. The process for fabricating the laser cavity of claim 1, wherein said monocrystalline compound semiconductor layer is selected fo r an infrared light emission.

25. The process for fabricating the laser cavity of claim 1, wherein said monocrystalline compound semiconductor layer is selected from the group consisting of InP, InGaAs, InAlAs, InGaAlAs, InGaAsP and InGaAsN.

26. The process for fabricating the laser cavity of claim 1, wherein said first cleave indentation is formed along a crystal plane of said monocrystalline compound semiconductor layer.

27. The process for fabricating the laser cavity of claim 1, wherein said second cleave indentation is formed along a crystal plane of said monocrystalline compound semiconductor layer.

28. A semiconductor structure, comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material, said monocrystalline compound semiconductor material having a laser cavity with a first facet; and
a first outer wall in said monocrystalline compound semiconductor material having a non-parallel orientation with respect to said first facet of said laser cavity.

29. The semiconductor structure of claim 28, further comprising a second outer wall in said monocrystalline compound semiconductor material having a non-parallel orientation with respect to a second facet of said laser cavity.

30. The semiconductor structure of claim 28, wherein said first facet has an anti-reflective coating.

31. The semiconductor structure of claim 29, wherein said second facet has an anti-reflective coating.

32. The semiconductor structure of claim 28, wherein said monocrystalline compound semiconductor layer is selected for a visible light emission.

33. The semiconductor structure of claim 28, wherein said monocrystalline compound semiconductor layer is selected from the group consisting of InGaP, In AIP, INGaAIP, GaN, InGaN and InGaAIN.

34. The semiconductor structure of claim 28, wherein said monocrystalline compound semiconductor layer is selected for a near infrared light emission.

35. The semiconductor structure of claim 28, wherein said monocrystalline compound semiconductor layer is selected from the group consisting of GaAs, AlGaAs, InGaAs, InGaAlAs and InGaAsP.

36. The semiconductor structure of claim 28, wherein said monocrystalline compound semiconductor layer is selected for an infrared light emission

37. The semiconductor structure of claim 28, wherein said monocrystalline compound semiconductor layer is selected from the group consisting of InP, InGaAs, InAlAs, InGaAlAs, InGaAsP and InGaAsN.

38. The semiconductor structure of claim 28, further comprising an optical wave guide in alignment with said first facet of said laser cavity.

39. The semiconductor structure of claim 29, further comprising a laser control circuit operatively coupled to said laser cavity.
